(19) United States
(12) Patent Application Publication
(10) Pub. No.: US 2024/0404601 A1
(43) Pub. Date: Dec. 5, 2024

(54) ALTERNATING BITLINE PAGE MAPPING WITH LINEAR WORDLINE RAMPING DURING A READ OPERATION

(71) Applicant: Micron Technology, Inc., Boise, ID (US)

(72) Inventor: Tomoharu Tanaka, Yokohama (JP)

(21) Appl. No.: 18/624,570

(22) Filed: Apr. 2, 2024

Related U.S. Application Data
(60) Provisional application No. 63/469,616, filed on May 30, 2023.

(51) Int. Cl. G11C 16/10; G11C 16/04; G11C 16/26

(52) U.S. Cl. CPC G11C 16/102; G11C 16/0433; G11C 16/26

(57) ABSTRACT

Control logic in a memory device initiating a program operation to program a set of memory cells associated with a set of pages comprising a lower page, an upper page, an extra page, and a top page of a memory device. During the program operation, first data of the lower page and the upper page is programmed into a first subset of memory cells connected to a first subset of even-numbered bitlines associated with a target wordline of the memory device. During the program operation, second data of the extra page and the top page is programmed into a second subset of memory cells connected to a second subset of odd-numbered bitlines associated with the target wordline of the memory device.

### CROSS-REFERENCE TO RELATED APPLICATION

This application claims the benefit of U.S. Provisional Application No. 63/469,616, titled “Alternating Bitline Page Mapping With Linear Wordline Ramping During A Read Operation,” filed May 30, 2023, which is hereby incorporated herein by reference in its entirety.

### TECHNICAL FIELD

Embodiments of the disclosure relate generally to memory sub-systems, and more specifically, relate to alternating bitline page mapping with linear wordline ramping during a read operation associated with a memory device in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system, in accordance with one or more embodiments of the present disclosure.

FIG. 1B is a block diagram of a memory device in communication with a memory sub-system controller of a memory sub-system, in accordance with one or more embodiments of the present disclosure.

FIG. 2A-2D are schematics of portions of an array of memory cells as could be used in a memory of the type described with reference to FIG. 1B, in accordance with one or more embodiments of the present disclosure.

FIG. 3 is a block schematic of a portion of an array of memory cells as could be used in a memory of the type described with reference to FIG. 1B, in accordance with one or more embodiments of the present disclosure.

FIG. 4 illustrates an example data mapping scheme used to program memory cells to map a first set of multiple pages of the memory device that are connected to a target wordline and a first set of even-numbered bitlines, in accordance with one or more embodiments of the present disclosure.

FIG. 5 illustrates an example data mapping scheme used to program memory cells to map a second set of multiple pages of the memory device that are connected to the target wordline and a second set of odd-numbered bitlines, in accordance with one or more embodiments of the present disclosure.

FIGS. 6A and 6B illustrate example wordline ramping voltages applied to a target wordline during a read operation of a target page of a memory device programmed using alternating bitline page mapping, in accordance with one or more embodiments of the present disclosure.

FIG. 7 is a flow diagram of an example method of implementing alternating bitline page mapping to store data to a set of memory cells of a memory device, in accordance with one or more embodiments of the present disclosure.

FIG. 8 is a block diagram of an example computer system in which embodiments of the present disclosure may operate.

### DETAILED DESCRIPTION

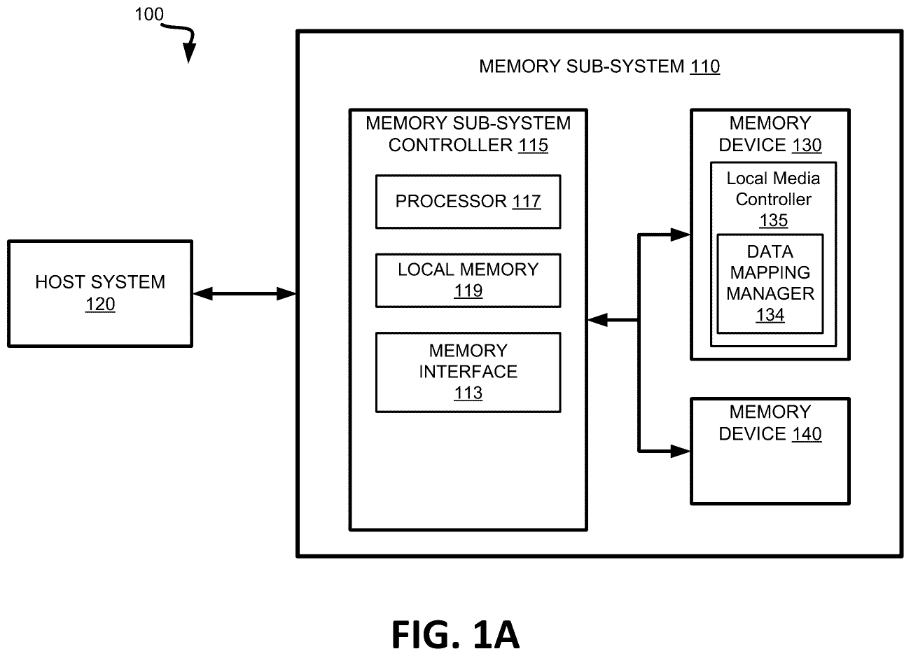

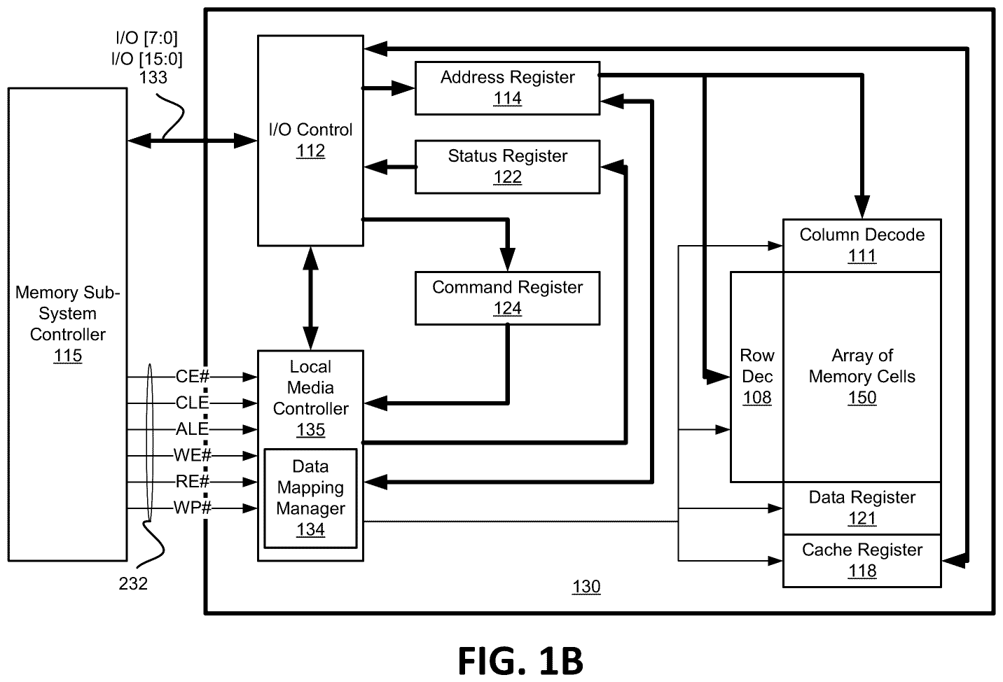

Aspects of the present disclosure are directed to alternating bitline page mapping with linear wordline ramping during a read operation to read data associated with a memory device in a memory sub-system. A memory sub-system can be a storage device, a memory module, or a combination of a storage device and memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a NOT-and (NAND) memory device. Other examples of non-volatile memory devices are described below in conjunction with FIG. 1A. A non-volatile memory device is a package of one or more dice. Each die can include two or more planes. For some types of non-volatile memory devices (e.g., NAND devices), each plane includes of a set of physical blocks. In some implementations, each block can include multiple sub-blocks. Each plane carries a matrix of memory cells formed on a silicon wafer and joined by conductors referred to as wordlines (WLs) and bitlines (BLs), such that a wordline joins multiple memory cells forming a row of the matrix of memory cells, while a bitline joins multiple memory cells forming a column of the matrix of memory cells.

Depending on the cell type, each memory cell can store one or more bits of binary information, and has various logic states that correlate to the number of bits being stored. The logic states can be represented by binary values, such as “0” and “1,” or combinations of such values, also referred to herein as logical bit values. A memory cell can be programmed (written to) by applying a certain voltage to the memory cell, which results in an electric charge being held by the memory cell, thus allowing modulation of the voltage distributions produced by the memory cell. A set of memory cells referred to as a memory page can be programmed together in a single operation, e.g., by selecting consecutive bitlines.

Precisely controlling the amount of the electric charge stored by the memory cell allows establishing multiple logical levels, thus effectively allowing a single memory cell to store multiple bits of information. A read operation can be performed by comparing the measured threshold voltages (Vₜ) exhibited by the memory cell to one or more reference voltage levels in order to distinguish between two logical levels for single-level cell (SLCs) and between multiple logical levels for multi-level cells. A memory device can include multiple portions, including, e.g., one or more portions where the sub-blocks are configured as SLC memory and one or more portions where the sub-blocks are configured as multi-level cell (MLC) memory that can store three bits of information per cell and/or (triple-level cell) TLC memory that can store three bits of information per cell. The voltage levels of the memory cells in TLC memory form a set of 8 programming (or threshold voltage (Vₜ)) distributions representing the 8 different combinations of the three bits stored in each memory cell. Depending on how the memory cells are configured, each physical memory page in one of the sub-blocks can include multiple page types. For example, a physical memory page formed from SLC memory cells has a single page type referred to as a lower logical page (LP). Multi-level cell (MLC) physical page types can include LPs and upper logical pages (UPs) and store two bits of information per cell. Further, TLC physical page types can include LPs, UPs, and extra logical pages (XPs) and store three bits of information per cell. Further, quad-level (QLC) physical page types can include LPs, UPS, XPs and top logical pages (TPs) and store four bits of information per cell. For example, a physical memory page formed from memory cells of the QLC memory type have a total of four logical pages, where each logical page stores data distinct from the data stored in the other logical pages associated with that physical memory page, herein referred to as a “page.”

A memory device can be made up of bits arranged in a two-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including the different page types (e.g., LPs, UPs, XPs, and TPs).

In certain QLC memory devices, page mapping includes programming data associated with the four logical pages (e.g., LP, UP, XP, and TP) into memory cells that share a same or common wordline (also referred to as a “target wordline” or “WLn”). According to this page mapping approach, each QLC memory cell includes a first bit associated with a first subset of data (e.g., 16 KB) from a lower page, a second bit associated with a second subset of data from an upper page, a third bit associated with a third subset of data from an extra page, and a fourth bit associated with a fourth subset of data from a top page. For example, a memory cell can be programmed using this page mapping approach to store a bit sequence of “1010”, where the first bit position (e.g., “1”) is based on the LP type, the second bit position (e.g., “0”) is based on the UP type, the third bit position (e.g., “1”) is based on the XP type, and the fourth bit position (e.g., “1”) is based on the TP type.

Accordingly, due to the manner in which the logical pages are mapped, execution of a read operation of a particular page type (e.g., a target XP) requires all of the bitlines to be accessed to read the bit value of a target bit position (e.g., a third bit position associated with a target XP) of all of the memory cells. In this regard, a read operation to determine the data stored in the target XP data requires sensing of all of the bitlines (e.g., BL0, BL1, BL2 . . . BLn) corresponding to the target wordline (WLn).

Furthermore, to avoid the effects of bitline-to-bitline capacitive coupling, when the even-numbered bitlines are sensed, the odd-numbered bitlines are grounded to shield those bitlines. Similarly, when the odd-numbered bitlines are sensed, the even-numbered bitlines are grounded. To sense a subset of bitlines (e.g., the even-numbered bitlines), all bitlines are initially pre-charged to a target voltage level. After pre-charging the bitlines, the selected bitlines (e.g., the even-numbered bitlines) are floated and a first linearly increasing or ramping voltage (Vw1) is applied to the target wordline (WLn). Similarly, when sensing the odd-numbered bitlines, a second linearly ramping voltage is applied to the target wordline.

Accordingly, sensing all of the bitlines (e.g., a set of even-numbered bitlines and a set of odd-numbered bitlines) requires a selected or target wordline to be ramped twice to read out a single selected or target page. Accordingly, before the data of the target page (e.g., an XP) can be read out or output, a first wordline ramping is required to sense the data from the multiple programmed levels (e.g., L0 to L15) for the even-numbered bitlines followed by a second wordline ramping to sense the data from the programmed levels (e.g., L0 to L15) for the odd-numbered bitlines. The execution of a read operation including multiple wordline ramping operations to read out data from a selected page results in a longer read latency.

Aspects of the present disclosure address the above and other deficiencies by implementing a page mapping scheme during a programming operation to store first data associated a first subset of logical pages (e.g., LPs and UPs) into memory cells connected to a first subset of even-numbered bitlines and a target wordline (WLn) and store second data associated with a second subset of logical pages (e.g., XPs and TPs) connected to a second subset of odd-numbered bitlines and the target wordline (WLn). In an embodiment, page mapping is executed by mapping data from logical pages to alternating subsets of bitlines (i.e., the even-numbered bitlines and the odd-numbered bitlines). In an embodiment, a first subset or group of logical page types (e.g., the LPs and UPs) are programmed into a first subset of memory cells connected to the even-numbered bitlines (e.g., BL0, BL2, BL4, etc.) corresponding to the target wordline. In addition, a second subset or group of logical page types (e.g., the XPs and TPs) are programmed into a second subset of memory cells connected to the odd-numbered bitlines (e.g., BL1, BL3, BL5, etc.).

According to embodiments, during a programming operation, a set of logical pages types (e.g., four pages including LPs, UPs, XPs, and TPs) are programmed into a selected or target wordline. Advantageously, using this page mapping scheme, a single wordline ramping of the target wordline is performed during execution of a read operation to read data associated with a target page. For example, if the selected or target page is part of the first subset of pages (e.g., an LP or a UP), a single wordline ramping voltage is applied to the target wordline to read the data stored in the memory cells corresponding to the even-numbered bitlines. In this regard, the read operation includes a single wordline ramping operation of the target wordline to read each of the bit positions corresponding to the selected page. Advantageously, the use of single wordline ramping sub-operation results in improved read performance due to the reduction of read latency.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, compute express link (CXL) interface). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a CXL interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level memory cells (SLC) can store one bit per memory cell. Other types of memory cells, such as multi-level memory cells (MLCs), triple level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCS, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory page buffers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

The local media controllers 135 can implement a data mapping manager 134 that can manage the mapping of data from logical page types to the array of memory cells using a first subset of bitlines (e.g., even-numbered bitlines) corresponding to a first subset of pages (e.g., LPs and UPs) and a second subset of bitlines (e.g., odd-numbered bitlines) corresponding to a second subset of pages (e.g., XPs and TPs). In an embodiment, the data mapping manager 134 executes one or more program operations during which the first data corresponding to a first subset of page types (e.g., LPs and UPs) is programmed into a first subset of memory cells connected to a target wordline and the even-numbered bitlines. In an embodiment, the data mapping manager 134 executes one or more program operations during which the second data corresponding to a second subset of page types (e.g., XPs and TPs) is programmed into a second subset of memory cells connected to the target wordline and the odd-numbered bitlines.

According to embodiments, the local media controller 135 identifies a request for the execution of a read operation of a selected page. In response to the request, the subset of bitlines corresponding to the memory cells that store the data of the selected page type (e.g., the even-numbered bitlines or the odd-numbered bitlines) are identified. During the read operation, a single wordline ramping on a target wordline to access the memory cells storing the selected page that correspond to the identified subset of bitlines (i.e., either the even-numbered bitlines or the odd-numbered bitlines).

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 111 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address page buffer 114 is in communication with I/O control circuitry 160 and row decode circuitry 108 and column decode circuitry 111 to latch the address signals prior to decoding. A command page buffer 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 111 to control the row decode circuitry 108 and column decode circuitry 111 in response to the addresses. In one embodiment, local media controller 135 includes the data mapping manager 134, which can implement the page mapping scheme including placement of first data associated with a first subset of page types (e.g., LPs and UPs) into a first subset of memory cells of a first subset of bitlines (e.g., even-numbered bitlines) and placement of second data associated with a second subset of page types (e.g., XPs and TPs) into a second subset of memory cells of a second subset of bitlines (e.g., odd-numbered bitlines) during a programming operation of a set of target memory cells of the one or more memory devices 130.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 121 for transfer to the array of memory cells 104; then new data may be latched in the cache register 118 from the I/O control circuitry 160. During a read operation, data may be passed from the cache register 118 to the I/O control circuitry 160 for output to the memory sub-system controller 115; then new data may be passed from the data register 121 to the cache register 118. The cache register 118 and/or the data register 121 may form (e.g., may form a portion of) a page buffer of the memory device 130. A page buffer may further include sensing devices (not shown in FIG. 1B) to sense a data state of a memory cell of the array of memory cells 204, e.g., by sensing a state of a data line connected to that memory cell. A status page buffer 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command page buffer 124. The addresses may be received over input/output (I/O) pins [7:0] of I/O bus 136 at I/O control circuitry 160 and may then be written into address page buffer 114. The data may be received over input/output (I/O) pins [7:0] for an 8-bit device or input/output (I/O) pins [15:0] for a 16-bit device at I/O control circuitry 160 and then may be written into cache register 118. The data may be subsequently written into data register 121 for programming the array of memory cells 104.

In an embodiment, cache register 118 may be omitted, and the data may be written directly into data register 121. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

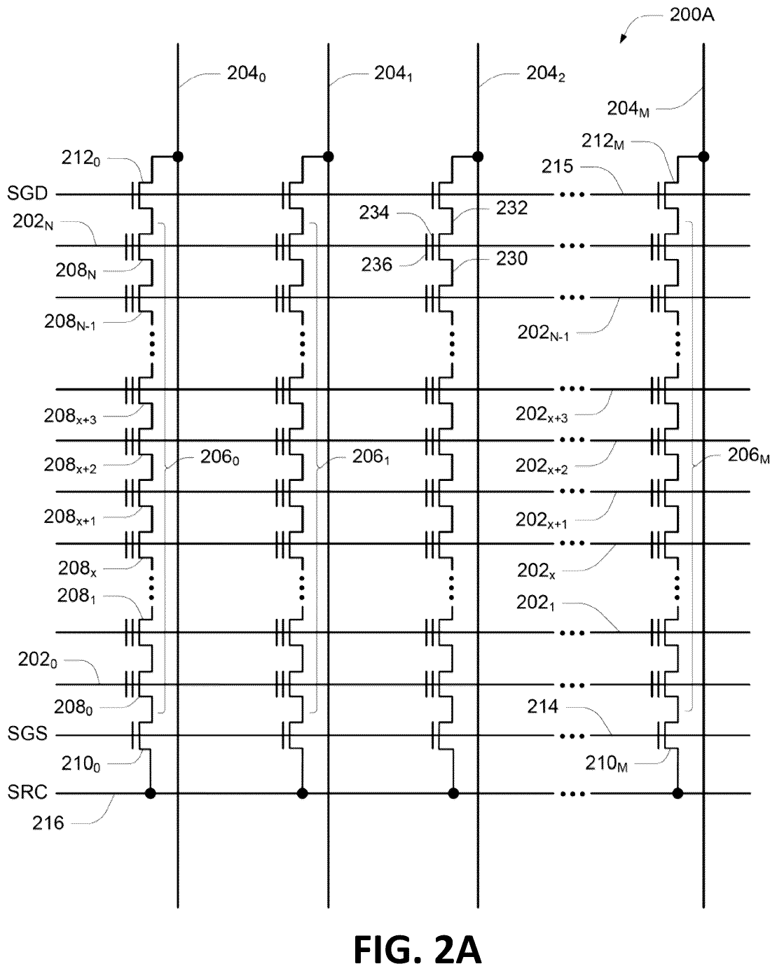

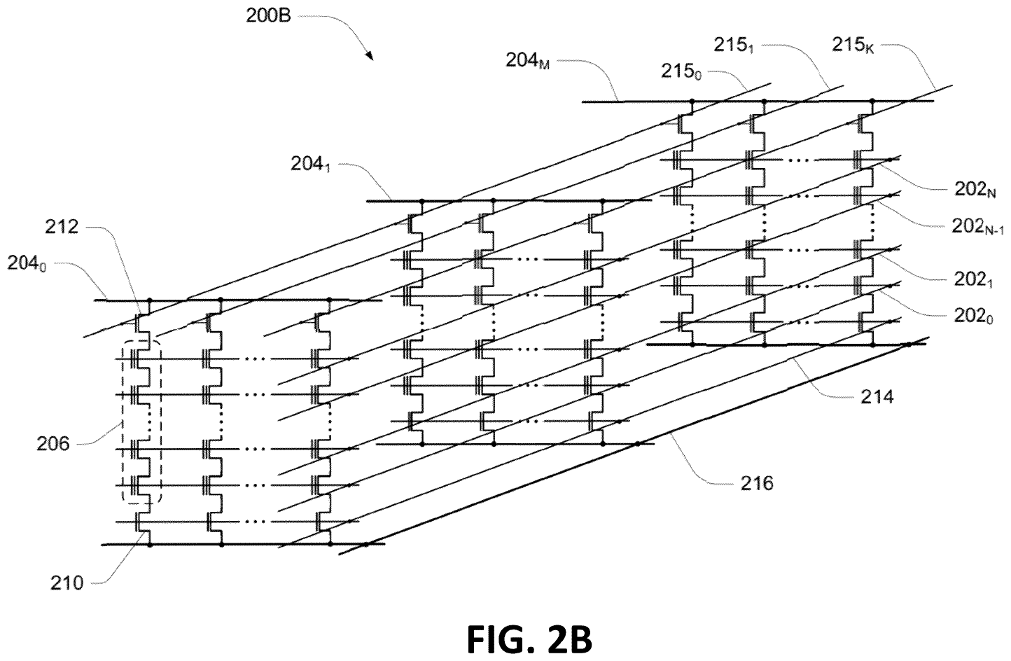

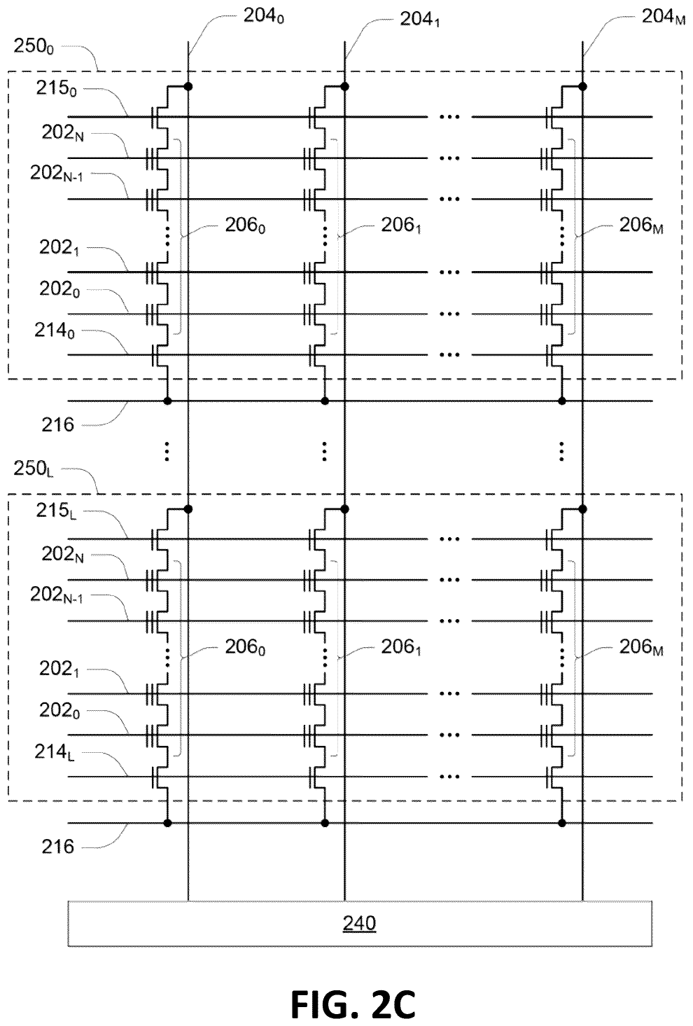

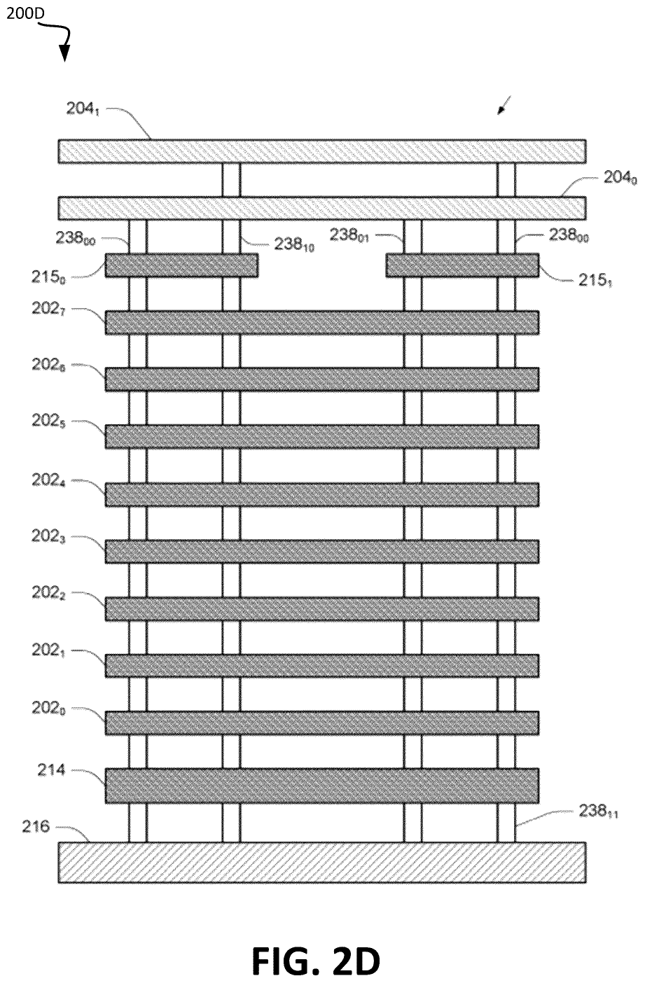

FIGS. 2A-2C are diagrams of portions of an example array of memory cells included in a memory device, in accordance with some embodiments of the present disclosure. For example, FIG. 2A is a schematic of a portion of an array of memory cells 200A as could be used in a memory device (e.g., as a portion of array of memory cells 104). Memory array 200A includes access lines, such as wordlines 202₀ to 202_{N}, and a data line, such as bitline 204. The wordlines 202 may be connected to global access lines (e.g., global wordlines), not shown in FIG. 2A, in a many-to-one relationship. For some embodiments, memory array 200A may be formed over a semiconductor that, for example, may be conductively doped to have a conductivity type, such as a p-type conductivity, e.g., to form a p-well, or an n-type conductivity, e.g., to form an n-well.

Memory array 200A can be arranged in rows each corresponding to a respective wordline 202 and columns each corresponding to a respective bitline 204. Rows of memory cells 208 can be divided into one or more groups of physical pages of memory cells 208, and physical pages of memory cells 208 can include every other memory cell 208 commonly connected to a given wordline 202. For example, memory cells 208 commonly connected to wordline 202_{N} and selectively connected to even bitlines 204 (e.g., bitlines 204₀, 204₂, 204₄, etc.) may be one physical page of memory cells 208 (e.g., even memory cells) while memory cells 208 commonly connected to wordline 202_{N} and selectively connected to odd bitlines 204 (e.g., bitlines 204₁, 204₃, 204₅, etc.) may be another physical page of memory cells 208 (e.g., odd memory cells). Although bitlines 204₃-204₅ are not explicitly depicted in FIG. 2A, it is apparent from the figure that the bitlines 204 of the array of memory cells 200A may be numbered consecutively from bitline 204₀ to bitline 204_{M}. Other groupings of memory cells 208 commonly connected to a given wordline 202 may also define a physical page of memory cells 208. For certain memory devices, all memory cells commonly connected to a given wordline might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells may include those memory cells that are configured to be erased together, such as all memory cells connected to wordlines 202₀-202_{N} (e.g., all strings 206 sharing common wordlines 202). Unless expressly distinguished, a reference to a page of memory cells herein refers to the memory cells of a logical page of memory cells.

Each column can include a string of series-connected memory cells (e.g., non-volatile memory cells), such as one of strings 206₀ to 206_{M}. Each string 206 can be connected (e.g., selectively connected) to a source line 216 (SRC) and can include memory cells 208₀ to 208_{N}. The memory cells 208 of each string 206 can be connected in series between a select gate 210, such as one of the select gates 210₀ to 210_{M}, and a select gate 212, such as one of the select gates 212₀ to 212_{M}. In some embodiments, the select gates 210₀ to 210_{M} are source-side select gates (SGS) and the select gates 212₀ to 212_{M} are drain-side select gates. Select gates 210₀ to 210_{M} can be connected to a select line 214 (e.g., source-side select line) and select gates 212₀ to 212_{M} can be connected to a select line 215 (e.g., drain-side select line). The select gates 210 and 212 might represent a plurality of select gates connected in series, with each select gate in series configured to receive a same or independent control signal. A source of each select gate 210 can be connected to SRC 216, and a drain of each select gate 210 can be connected to a memory cell 208₀ of the corresponding string 206. Therefore, each select gate 210 can be configured to selectively connect a corresponding string 206 to SRC 216. A control gate of each select gate 210 can be connected to select line 214. The drain of each select gate 212 can be connected to the bitline 204 for the corresponding string 206. The source of each select gate 212 can be connected to a memory cell 208_{N} of the corresponding string 206. Therefore, each select gate 212 might be configured to selectively connect a corresponding string 206 to the bitline 204. A control gate of each select gate 212 can be connected to select line 215.

In some embodiments, and as will be described in further detail below with reference to FIG. 2B, the memory array in FIG. 2A is a three-dimensional memory array, in which the strings 206 extend substantially perpendicular to a plane containing SRC 216 and to a plane containing a plurality of bitlines 204 that can be substantially parallel to the plane containing SRC 216.

FIG. 2B is another schematic of a portion of an array of memory cells 200B (e.g., a portion of the array of memory cells 104) arranged in a three-dimensional memory array structure. The three-dimensional memory array 200B may incorporate vertical structures which may include semiconductor pillars where a portion of a pillar may act as a channel region of the memory cells of strings 206. The strings 206 may be each selectively connected to a bit line 204₀-204_{M} by a select gate 212 and to the SRC 216 by a select gate 210. Multiple strings 206 can be selectively connected to the same bitline 204. Subsets of strings 206 can be connected to their respective bitlines 204 by biasing the select lines 215₀-215_{L} to selectively activate particular select gates 212 each between a string 206 and a bitline 204. The select gates 210 can be activated by biasing the select line 214. Each wordline 202 may be connected to multiple rows of memory cells of the memory array 200B. Rows of memory cells that are commonly connected to each other by a particular wordline 202 may collectively be referred to as tiers.

FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation, sometimes referred to as erase blocks. Each block of memory cells 250 can represent those NAND strings 206 commonly associated with a single select line 215, e.g., select line 215₀. The source 216 for the block of memory cells 250₀ can be a same source as the source 216 for the block of memory cells 250_{L}. For example, each block of memory cells 250₀-250_{L}, can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bitlines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bitlines 204.

FIG. 2D is a diagram of a portion of an array of memory cells 200D (e.g., a portion of the array of memory cells 104). Channel regions (e.g., semiconductor pillars) 238₀₀ and 238₀₁ represent the channel regions of different strings of series-connected memory cells (e.g., strings 206 of FIGS. 2A-2C) selectively connected to the bitline 204₀. Similarly, channel regions 238₁₀ and 238₁₁ represent the channel regions of different strings of series-connected memory cells (e.g., NAND strings 206 of FIGS. 2A-2C) selectively connected to the bitline 204₁. A memory cell (not depicted in FIG. 2D) may be formed at each intersection of an wordline 202 and a channel region 238, and the memory cells corresponding to a single channel region 238 may collectively form a string of series-connected memory cells (e.g., a string 206 of FIGS. 2A-2C). Additional features might be common in such structures, such as dummy wordlines, segmented channel regions with interposed conductive regions, etc.

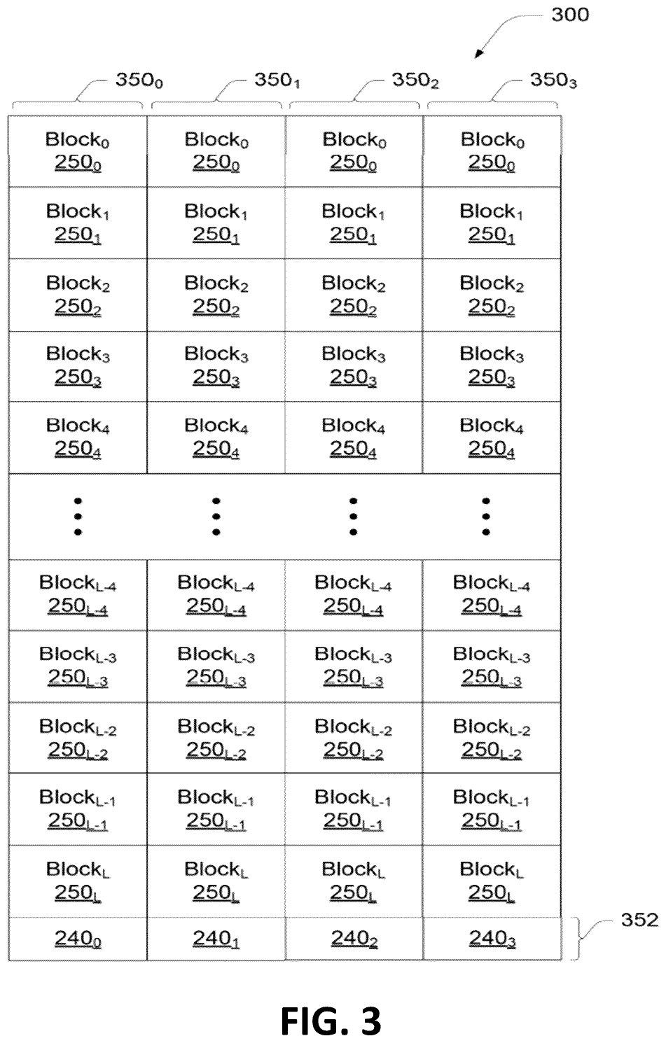

FIG. 3 is a block schematic of an example portion of an array of memory cells 300 as could be used in a memory of the type described with reference to FIG. 1B. The array of memory cells 300 is depicted as having four memory planes 350 (e.g., memory planes 350₀-350₃), each in communication with a respective buffer portion 240, which can collectively form a page buffer 352. While four memory planes 350 are depicted, other numbers of memory planes 350 can be commonly in communication with a page buffer 352. Each memory plane 350 is depicted to include L+1 blocks of memory cells 250 (e.g., blocks of memory cells 250₀-250_{L}).

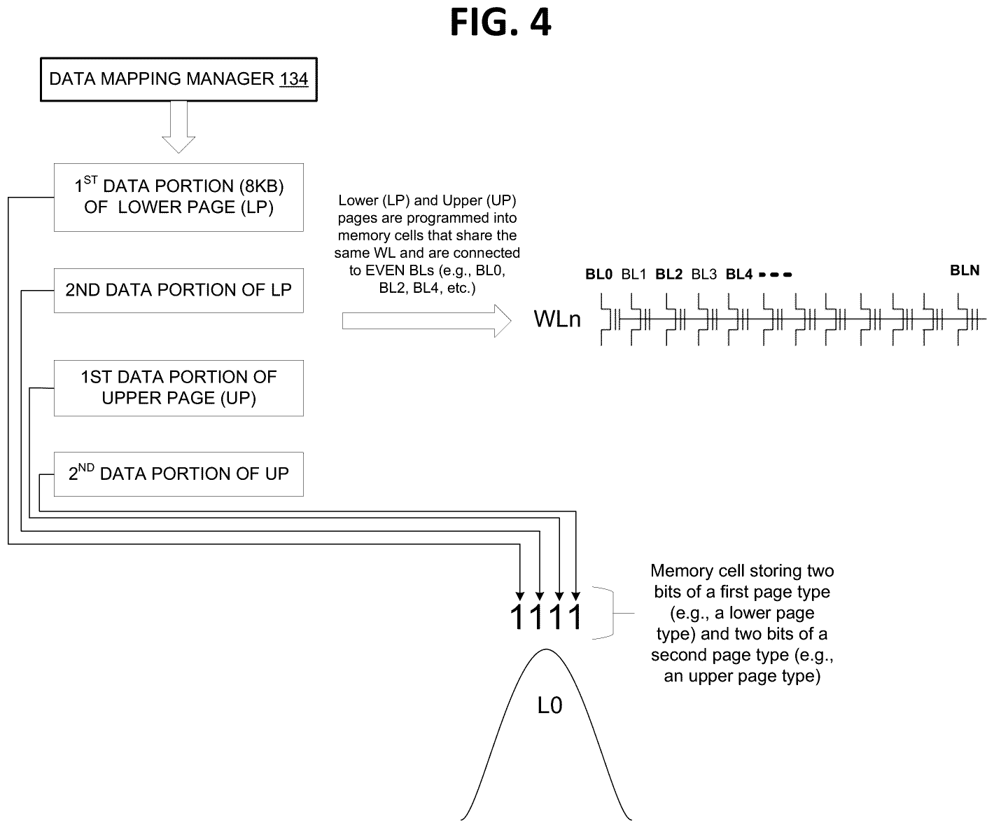

FIG. 4 illustrates an example data mapping scheme during programming of a set of target memory cells of a memory device in accordance with embodiments of the present disclosure. In one embodiment, the data mapping scheme is performed by control logic (e.g., data mapping manager 134) of the memory device. FIG. 4 illustrates a first portion of the data mapping scheme where first data associated with a first subset of logical pages (e.g., lower pages (LP) and upper pages (UP)) are programmed into a first subset of memory cells connected to a target wordline (WLn) and a first subset of bitlines. As illustrated, a first data portion (e.g., a first subset of 8 KB of data) of a lower page (LP) and a second data portion (e.g., a second subset of 8 KB of data) of the lower page are programmed into a first subset of memory cells connected to the even-numbered bitlines (e.g., BL0, BL2, BL4 . . . BN, where N is an even number).

As shown, the first data portion of the lower page is programmed into a first bit position of selected or target memory cells of a programming distribution (e.g., L0) of a set of programming distributions (e.g., L0, L1, L2 . . . L15) and the second data portion of the lower page is programmed into a second bit position of the one or more selected or target memory cells of the programming distribution (L0) of the set of programming distributions (e.g., L0 to L15).

As illustrated, a first data portion (e.g., a first subset of 8 KB of data) of an upper page (UP) and a second data portion (e.g., a second subset of 8 KB of data) of the upper page are programmed into the first subset of memory cells connected to the even-numbered bitlines (e.g., BL0, BL2, BL4 . . . BN, where N is an even number).

As shown, the first data portion of the upper page is programmed into a third bit position of selected or target memory cells of a programming distribution (e.g., L0) of a set of programming distributions (e.g., L0, L1, L2 . . . L15) and the second data portion of the upper page is programmed into a fourth bit position of the one or more selected or target memory cells of the programming distribution (L0) of the set of programming distributions (e.g., L0 to L15).

Accordingly, the page mapping scheme employed by the data mapping manager 134 enables memory cells connected to the even-numbered bitlines to store data corresponding to a first subset of page types. In the example shown in FIG. 4, the first subset of page types includes the lower pages and the upper pages.

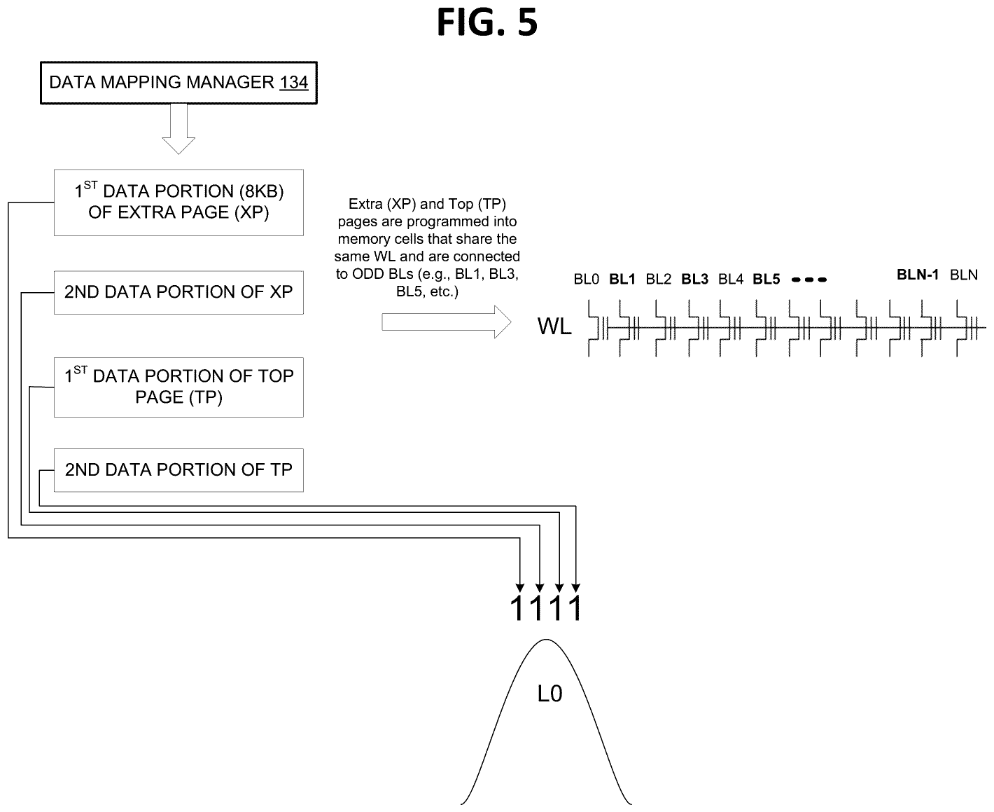

FIG. 5 illustrates a portion of the data mapping scheme employed by the data mapping manager 134 in association with a program operation. In addition to the data mapping of the first page types (e.g., LP and UP) to memory cells associated with the even-numbered bitlines, the data mapping manager 134 performs data mapping using the odd-numbered bitlines. As illustrated in FIG. 5, second data associated with a second subset of logical pages (e.g., extra pages (XP) and top pages (TP)) are programmed into a second subset of memory cells connected to the target wordline (WLn) and a second subset of bitlines. As illustrated, a first data portion (e.g., a first subset of 8 KB of data) of an extra page (XP) and a second data portion (e.g., a second subset of 8 KB of data) of the extra page are programmed into a second subset of memory cells connected to the odd-numbered bitlines (e.g., BL1, BL3, BL5 . . . BN-1, where N is an even number).

As shown, the first data portion of the extra page is programmed into a first bit position of selected or target memory cells of a programming distribution (e.g., L0) of a set of programming distributions (e.g., L0, L1, L2 . . . L15) and the second data portion of the extra page is programmed into a second bit position of the one or more selected or target memory cells of the programming distribution (L0) of the set of programming distributions (e.g., L0 to L15).

As illustrated, a first data portion (e.g., a first subset of 8 KB of data) of a top page (TP) and a second data portion (e.g., a second subset of 8 KB of data) of the top page are programmed into the second subset of target memory cells connected to the odd-numbered bitlines (e.g., BL1, BL3, BL5 . . . BN-1, where N is an even number).

As shown, the first data portion of the top page is programmed into a third bit position of selected or target memory cells of a programming distribution (e.g., L0) of a set of programming distributions (e.g., L0, L1, L2 . . . L15) and the second data portion of the top page is programmed into a fourth bit position of the one or more selected or target memory cells of the programming distribution (L0) of the set of programming distributions (e.g., L0 to L15).

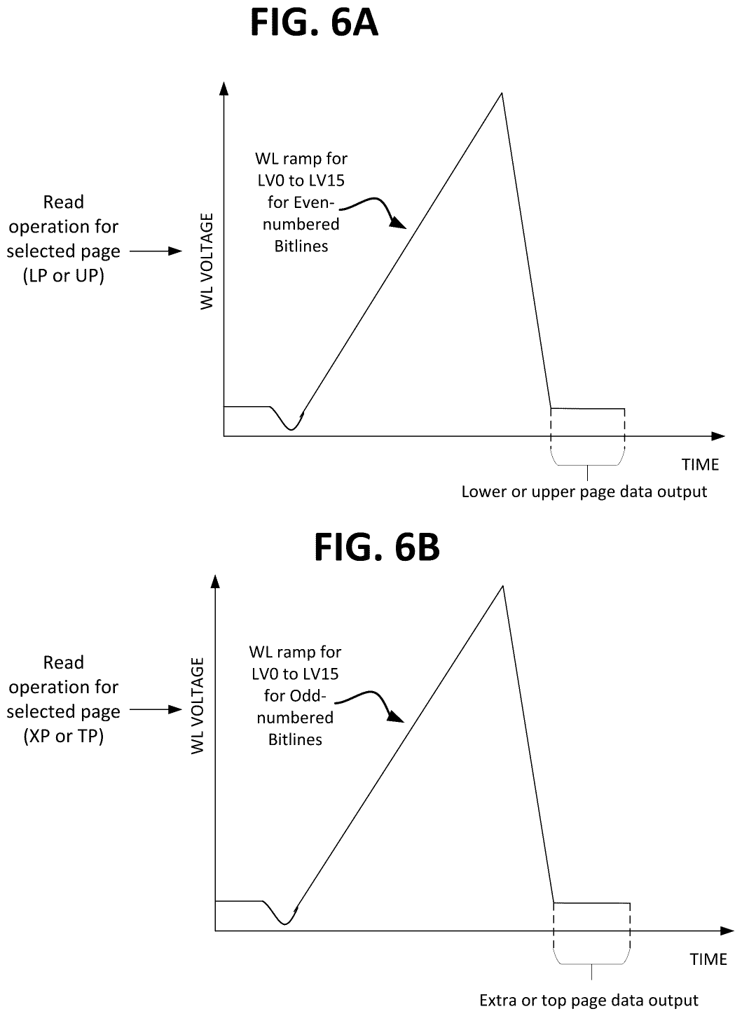

Accordingly, the page mapping scheme employed by the data mapping manager 134 shown in FIG. 4 and FIG. 5 enables execution of a read operation to read data of a selected or target page to include a single wordline voltage ramping to read all of the bit positions corresponding to the target page. As shown in FIGS. 6A and 6B, according to embodiments, the single wordline ramping voltage can be applied to a target wordline to read the data of the program distributions (e.g., L0 to L15 of a QLC memory device) associated with target memory cells storing the target page data by accessing a portion of the bitlines (e.g., the even-numbered bitlines as shown in FIG. 6A or the odd-numbered bitlines as shown in FIG. 6B).

For example, as shown in FIG. 6A, in response to a request for a read operation of either a target lower page or a target upper page, a single wordline ramping operation is performed to access the data stored in a subset of memory cells connected to the even-numbered bitlines. As shown in FIG. 6A, the data of the target lower page or target upper page can be output pursuant to the read operation following the single wordline ramping operation.

In another example shown in FIG. 6B, in response to a request for a read operation of either a target extra page or a target top page, a single wordline ramping operation is performed to access the data stored in a subset of memory cells connected to the odd-numbered bitlines. As shown in FIG. 6B, the data of the target lower page or target upper page can be output pursuant to the read operation following the single wordline ramping operation. Accordingly, as shown in FIGS. 6A and 6B, a single wordline ramping operation is needed to read out the data corresponding to all of the bit positions (e.g., bit position 1 to bit position 4) of the memory cells storing data of the target page. Advantageously, implementing the data mapping scheme described with respect to FIGS. 4-6B reduces the read latency associated with a subsequent read operation as compared to data mapping schemes which require read operations having multiple wordline ramping operations to read out all of the data associated with all of the bit positions of a target page.

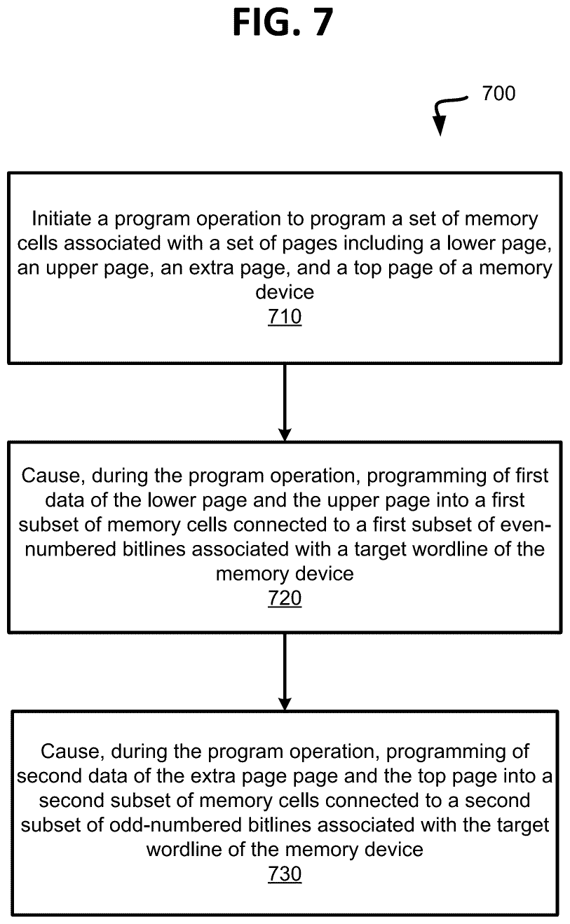

FIG. 7 is a flow diagram of an example method of implementing alternating bitline page mapping to store data to a set of memory cells of a memory device. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by data mapping manager 134 of FIGS. 1A, 1B, 4, and 5. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 710, a program operation is initiated. For example, the processing logic (e.g., the data mapping manager 134 of FIGS. 1A, 1B, 4 and 5) can initiate a program operation to program a set of memory cells associated with a set of pages including a lower page (LP), an upper page (UP), an extra page (XP), and a top page (TP) of a memory device. According to embodiments, the set of memory cells to be programmed (i.e., target memory cells) are associated with a target wordline (WLn) and a set of bitlines.

At operation 820, a first programming is performed. For example, the processing logic can cause, during the program operation, programming of first data of the lower page and the upper page into a first subset of memory cells connected to a first subset of even-numbered bitlines associated with the target wordline of the memory device. In an embodiment, the first data associated with the lower page and upper page is mapped by the processing logic to the first subset of memory cells connected to the even-numbered bitlines (e.g., BL0, BL2, BL4 . . . BLN, where N is an even number).

At operation 830, a second programming is performed. For example, the processing logic can cause, during the program operation, programming of second data of the extra page and the top page into a second subset of memory cells connected to a second subset of odd-numbered bitlines associated with the target wordline of the memory device. In an embodiment, the second data associated with the extra page and top page is mapped by the processing logic to the second subset of memory cells connected to the odd-numbered bitlines (e.g., BL1, BL3, BL5 . . . BLN-1, where N is an even number).

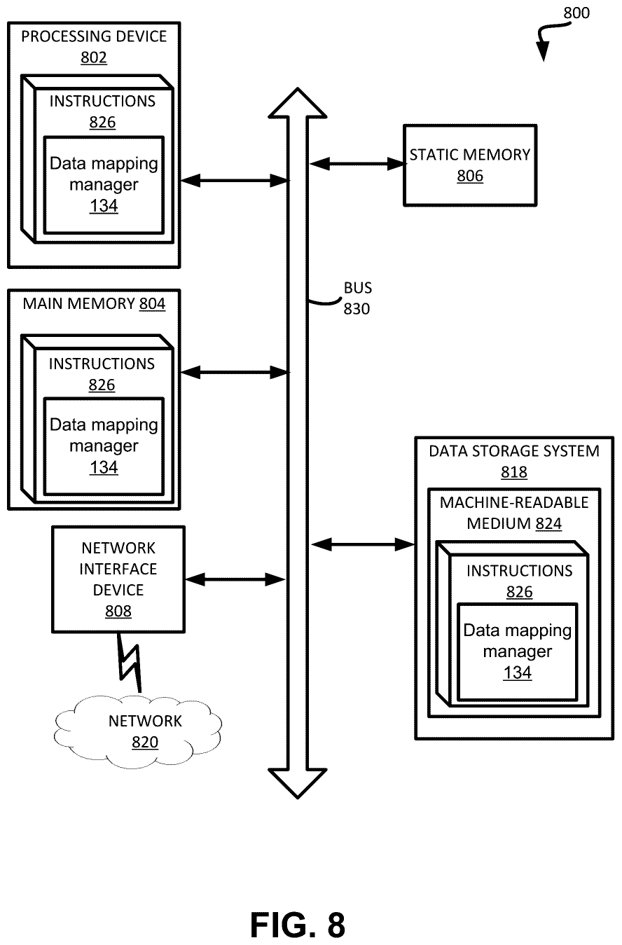

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the data mapping manager 134 of FIG. 1A, FIG. 1B, and FIG. 4). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a memory cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or RDRAM, etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein. The computer system 800 can further include a network interface device 808 to communicate over the network 820.

The data storage system 818 can include a machine-readable storage medium 824 (also known as a computer-readable medium) on which is stored one or more sets of instructions 826 or software embodying any one or more of the methodologies or functions described herein. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1A.

In one embodiment, the instructions 826 include instructions to implement functionality corresponding to a program manager (e.g., the data mapping manager 134 of FIG. 1A, FIG. 1B, FIG. 4, and FIG. 5). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's page buffers and memories into other data similarly represented as physical quantities within the computer system memories or page buffers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a set of memory cells; and
control logic, operatively coupled with the memory array, to perform operations comprising:
initiating a program operation to program the set of memory cells associated with a set of pages comprising a lower page, an upper page, an extra page, and a top page of the memory device;
causing, during the program operation, programming of first data of the lower page and the upper page into a first subset of memory cells connected to a first subset of even-numbered bitlines associated with a target wordline of the memory device; and
causing, during the program operation, programming of second data of the extra page and the top page into a second subset of memory cells connected to a second subset of odd-numbered bitlines associated with the target wordline of the memory device.

2. The memory device of claim 1, the operations further comprising receiving a request to execute a read operation of one of a selected lower page or a selected upper page.

3. The memory device of claim 2, the operations further comprising executing the read operation to read a subset of data from one of the selected lower page or the selected upper page, wherein executing the read operation comprises:
causing application of a ramping voltage to the target wordline and accessing one or more of the even-numbered bitlines; and
causing an output of the first subset of data following completion of the application of the ramping voltage.

4. The memory device of claim 1, the operations further comprising receiving a request to execute a read operation of one of a selected extra page or a selected top page.

5. The memory device of claim 4, the operations further comprising executing the read operation to read a subset of data from one of the selected extra page or the selected top page, wherein executing the read operation comprises:
causing application of a ramping voltage to the target wordline and accessing one or more of the odd-numbered bitlines; and
causing an output of the subset of data following completion of the application of the ramping voltage.

6. The memory device of claim 1, wherein the first subset of memory cells comprises a first memory cell comprising a first set of bit positions comprising a first bit position and a second bit position storing data associated with the lower page.

7. The memory device of claim 6, wherein the first set of bit positions comprises a third bit position and a fourth bit position storing data associated with the top page.

8. A method comprising:
initiating, by a processing device, a program operation to program a set of memory cells associated with a set of pages comprising a lower page, an upper page, an extra page, and a top page of a memory device;
causing, during the program operation, programming of first data of the lower page and the upper page into a first subset of memory cells connected to a first subset of even-numbered bitlines associated with a target wordline of the memory device; and
causing, during the program operation, programming of second data of the extra page and the top page into a second subset of memory cells connected to a second subset of odd-numbered bitlines associated with the target wordline of the memory device.

9. The method of claim 8, further comprising receiving a request to execute a read operation of one of a selected lower page or a selected upper page.

10. The method of claim 9, further comprising executing the read operation to read a subset of data from one of the selected lower page or the selected upper page, wherein executing the read operation comprises:
causing application of a ramping voltage to the target wordline and accessing one or more of the even-numbered bitlines; and
causing an output of the first subset of data following completion of the application of the ramping voltage.

11. The method of claim 8, further comprising receiving a request to execute a read operation of one of a selected extra page or a selected top page.

12. The method of claim 11, further comprising executing the read operation to read a subset of data from one of the selected extra page or the selected top page, wherein executing the read operation comprises:
causing application of a ramping voltage to the target wordline and accessing one or more of the odd-numbered bitlines; and
causing an output of the subset of data following completion of the application of the ramping voltage.

13. The method of claim 8, wherein the first subset of memory cells comprises a first memory cell comprising a first set of bit positions comprising a first bit position and a second bit position storing data associated with the lower page.

14. The method of claim 13, wherein the first set of bit positions comprises a third bit position and a fourth bit position storing data associated with the top page.

15. A non-transitory computer-readable storage medium comprising instructions that, when executed by a processing device, cause the processing device to perform operations comprising:
initiating a program operation to program a set of memory cells associated with a set of pages comprising a lower page, an upper page, an extra page, and a top page of a memory device;
causing, during the program operation, programming of first data of the lower page and the upper page into a first subset of memory cells connected to a first subset of even-numbered bitlines associated with a target wordline of the memory device; and
causing, during the program operation, programming of second data of the extra page and the top page into a second subset of memory cells connected to a second subset of odd-numbered bitlines associated with the target wordline of the memory device.

16. The non-transitory computer-readable storage medium of claim 15, the operations further comprising receiving a request to execute a read operation of one of a selected lower page or a selected upper page.

17. The non-transitory computer-readable storage medium of claim 16, the operations further comprising executing the read operation to read a subset of data from one of the selected lower page or the selected upper page, wherein executing the read operation comprises:
causing application of a ramping voltage to the target wordline and accessing one or more of the even-numbered bitlines; and
causing an output of the first subset of data following completion of the application of the ramping voltage.

18. The non-transitory computer-readable storage medium of claim 15, the operations further comprising receiving a request to execute a read operation of one of a selected extra page or a selected top page.

19. The non-transitory computer-readable storage medium of claim 18, the operations further comprising executing the read operation to read a subset of data from one of the selected extra page or the selected top page, wherein executing the read operation comprises:
causing application of a ramping voltage to the target wordline and accessing one or more of the odd-numbered bitlines; and
causing an output of the subset of data following completion of the application of the ramping voltage.

20. The non-transitory computer-readable storage medium of claim 15, wherein the first subset of memory cells comprises a first memory cell comprising a first set of bit positions comprising a first bit position and a second bit position storing data associated with the lower page; and wherein the first set of bit positions comprises a third bit position and a fourth bit position storing data associated with the top page.
